(19) United States
(12) Patent Application Publication
(10) Pub. No.: US 2003/0035158 A1
(43) Pub. Date: Feb. 20, 2003

(54) Method for saving and searching image adjusting parameter

(76) Inventor: Ching-Lai Tsai, Taipei Hsian (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/925,457

(22) Filed: Aug. 10, 2001

(51) Int. Cl. G03F 3/08

(52) U.S. Cl. 358/520; 358/519

(57) ABSTRACT

A method for saving and searching image adjusting parameter used in the saving and searching the contrast, brightness, and gamma adjusting parameter of digital image; wherein the parameter values are arranged in order into a plurality of memory address, and the critical values which are the minimum and the maximum of the output parameter range corresponsive to each of the input parameter, are saved in order into each of the foregoing addresses, thereby after the input parameter for the image adjustment is input, the maximum or minimum value in the corresponding input parameter range obtained from half of the memory address of the maximum output parameter value is compared with the foregoing input parameter value, and then repeat the binary search by this method until the matched range of memory address of the input parameter is searched, and further the corresponding output parameter of the image adjustment is obtained. The present invention is a method for saving and searching the image adjusting parameter of small memory capacity.

### BACKGROUND OF THE INVENTION

1. Field of the Invention

The present invention relates to a method for saving and searching image adjusting parameter, more particularly to a method for saving and searching image adjusting parameter used for the contrast, brightness, and gamma adjusting parameters.

2. Description of the Prior Art

Scanners or other equivalent image capture equipment are widely used in the capture and video data output of the digital image, and particularly scanning image has a good permanent backup and saving function for the paper image or data such as photographs, data, draft, etc, that will easily turn yellow when getting old. However, in scanning procedure of the scanner, it is necessary to have parameter adjustment when establishing and processing the digital image for appropriate contrast, brightness, and gamma correction. Particularly, these adjusting parameters will directly affect the quality and scanning effect of the output digital image.

Conventional charge coupled device (CCD) or contact image sensor (CIS) are converted into voltage signal, and then sent to the analog front end (AFE) or A/D converter for conversion into digital signal before being sent to the scanner controller. After the processing in the scanner controller and the correction made via the look-up table or tone mapping, the final digitized data is sent to the host by the interface end. The look-up table has the functions for adjusting the output parameter by contrast, brightness, and gamma correction.

Traditionally, the look-up table can correct images and in the meantime it also converts n bits of data (depending on the bits of AFE or A/D converter) into the mode of 8-bit or any number of bits. In the hardware architecture, it uses the 2ⁿ to 8-bit memory or the memory of 2ⁿ to any number of bits. It treats all values converted by one-to-one address mapping as the memory address of the same quantity, and the converted result is written into such address in advance. When the conversion is taking place, it does not require further computation, but directly read from the address instead. Converting n bits into an 8-bit format or any other number of bits format allows us to accurately calculate the required memory space as (2ⁿ×8) bits or (2ⁿ×m) bits, where m is an integer.

However, due to the actual image adjusting parameter and the parameter input value (adjusting command) corresponsive to the parameter output value is many-to-one mapping according to the above-mentioned method for saving the image adjusting parameter. Take 16-bit to 8-bit conversion for example, the 65536 input values are mapped into 256 output values. In other words, several input parameters in certain range correspond to the same output parameter, such that the repeated output parameter value is repeatedly saved into the corresponding address in the memory. Therefore, it occupies more address memory and space and reduces the performance of saving data.

In the above prior-art for saving image adjusting parameters, it actually is composed of three channels: red (R), green (G), and blue (B). These three channels have totally different properties, and thus each needs the memory for a look-up table. Take the 8-bit arrangement for example, the actual hardware required memory capacity is (2ⁿ×8)×3 bits. If 16-bit AFE or A/D converter is used, then it needs (2¹⁶×8×3) bits=1536K bits or (2¹⁶×m×3) bits of memory, where m is an integer.

From the analysis of the foregoing results, the traditional method for saving and searching image adjusting parameter is accomplished, and the obvious substantial shortcoming is that it needs a large memory, which will drastically increase in progression according to the number of bits of the AFE. As the AFE or A/D converter increases by 1 bit accuracy, then the memory required by the look-up table will be doubled. It will also increase the cost for circuitry and the difficulty in implementation, and will increase the overall size when it is applied to the scanner or other image capture device, which is not favorable to the product design and application.

In view of the shortcomings and inconvenience of the prior art mentioned above, which are the subjects of improvements for a long time, hence the inventor of the present invention based on years of experience accumulated from the engagement in the related industry conducted extensive research to resolve the foregoing shortcomings and invented the present invention as disclosed below.

### SUMMARY OF THE INVENTION

Therefore, the primary objective of the present invention is to provide a method for saving and searching image adjusting parameter by a simple and quick many-to-one parameter saving method such that it can reduce the memory space in great extent for the saved adjusting parameter, which is favorable for the design and application of the circuit and image capture products.

The secondary objective of the present invention is to provide a method for saving and searching image adjusting parameter such that the memory for saving the image adjusting parameter can totally avoid the repeated use of large amount of memory addresses and spaces to save the same data, and thus enhances the storage efficiency.

To attain the foregoing objectives, the method for saving and searching image adjusting parameter according to the present invention divides the output parameters in order into a plurality of memory addresses, and the critical values which are the minimum and the maximum of the output parameter range corresponsive to each of the input parameter, are saved in order into each of the foregoing addresses, thereby after the input parameter for the image adjustment is input, the maximum or minimum value in the corresponding input parameter range obtained from half of the memory address of the maximum output parameter value is compared with the foregoing input parameter value, and then repeat the binary search by this method until the matched range of memory address of the input parameter is searched, and further the corresponding output parameter of the image adjustment is obtained. The present invention drastically reduces the use of memory space and enhances the storage efficiency as well.

To make it easier for our examiner to understand the objective of the invention, structure, innovative features, and performance, we use a preferred embodiment together with the attached drawings for the detailed description of the invention.

### BRIEF DESCRIPTION OF THE DRAWINGS

Other objects, features, and advantages of the invention will become apparent from the following detailed description of the preferred but non-limiting embodiment. The description is made with reference to the accompanying drawings, in which:

FIG. 1 shows the corresponding function between the input parameter and the output parameter of the image adjusting parameter according to a first embodiment of the present invention.

FIG. 2 shows the flowchart of the searching method of the present invention.

FIG. 3 shows the corresponding function between the input parameter and the output parameter of the image adjusting parameter according to a second embodiment of the present

FIG. 4 shows the corresponding function between the input parameter and the output parameter of the image adjusting parameter according to a third embodiment of the present invention.

FIG. 5 shows the corresponding function between the input parameter and the output parameter of the image adjusting parameter according to a fourth embodiment of the present invention.

FIG. 6 shows the corresponding function between the input parameter and the output parameter of the image adjusting parameter according to a fifth embodiment of the present invention.

FIG. 7 shows the corresponding function between the input parameter and the output parameter of the image adjusting parameter according to a sixth embodiment of the present invention.

FIG. 8 shows the corresponding function between the input parameter and the output parameter of the image adjusting parameter according to a seventh embodiment of the present invention.

FIG. 9 shows the corresponding function between the input parameter and the output parameter of the image adjusting parameter according to an eighth embodiment of the present invention.

### DESCRIPTION OF THE PREFERRED EMBODIMENT

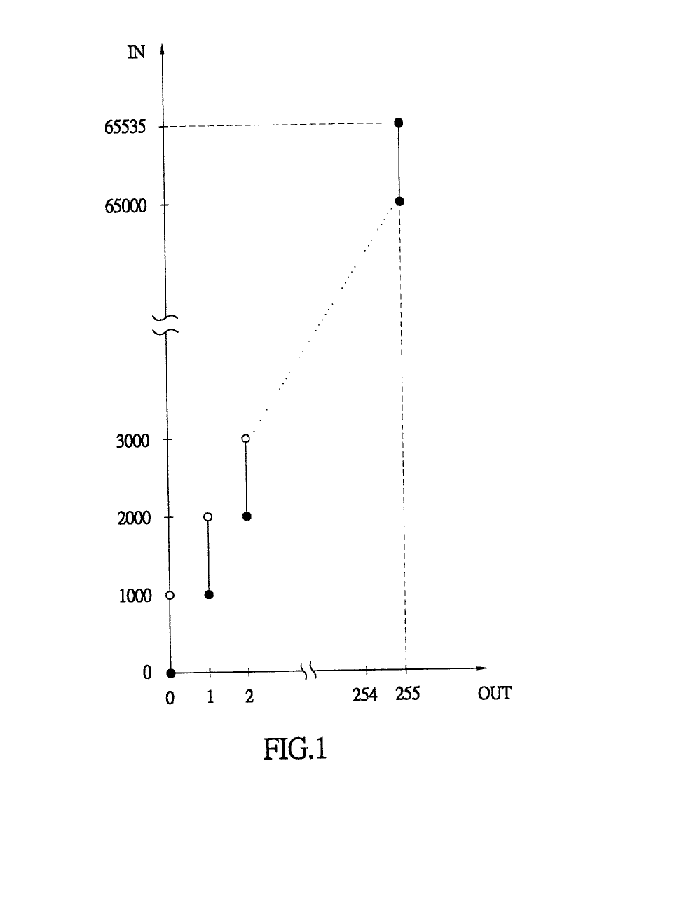

Please refer to FIG. 1 for the function mapping for the method of saving and searching image adjusting parameter according to the present invention. In an embodiment of the present invention, which use the 8-bit output parameter for example, and the output parameter is labeled with “OUT”, and the input parameter with “IN”. In FIG. 1, the IN value is represented by the vertical axis (Y-axis) and the OUT value is represented by the horizontal axis (X-axis).

The first embodiment as shown in FIG. 1 lists a many-to-one discrete increasing function mapping between the IN value and the OUT value, and the parameter ranges are 0≦IN≦65535; 0≦OUT≦255. However the function mapping of this type is not unchangeable, it may change according to the actual application of the adjustment for the image device. The relation of function mapping listed in the present invention is determined by the parameter adjustment requirement of the image capture and output for the scanner.

The number of IN values shown in FIG. 1 is 2¹⁶65536 and the number of corresponding OUT values is 2⁸=255. Each output parameter OUT has a range of corresponding input parameter IN from about 1000 to 2000. For example, when OUT=0, IN falls the range from 0 to 999; and when OUT=1, IN falls in the range from 1000 to 1999; when the OUT=255, the range of IN falls between 65000 to 65535. The OUT can be saved in the related memory address, and the present embodiment uses the memory address to stand for the OUT value. For example, if the memory address is 0($00), the corresponding OUT value is 0, and if the memory address is 255($FF), the corresponding OUT value is 255. Therefore, there is no need for complicated numerical conversion.

Further, we can save the maximum or minimum value in the IN range corresponsive to the OUT mapping function into each of the memory address. If the memory address is 0($00), the numeric value 999 is saved, and if 1($01), it saves the numeric value of 1999, and if the memory address is 255($FF), then it saves the numeric value of 65535. Therefore, the adjusting parameters such as the contrast, brightness, and gamma correction just need 256×16=4K bits of memory, and the total memory for the three adjusting parameter channels including R, B, and G just needs a total of 12K memory which is much smaller than the 1536 K bits of memory used for the one-to-one mapping look-up table. It simplifies and reduces the overall required memory circuit size, and the comparison between these two methods will be described in detail in the later section.

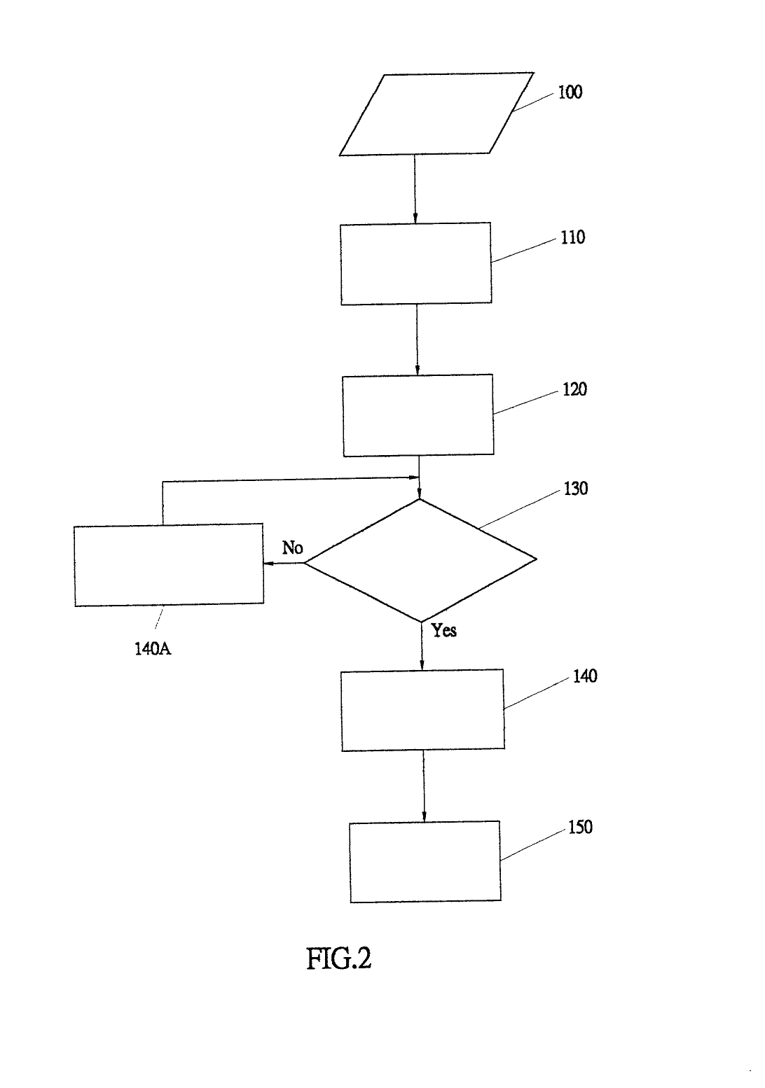

Please refer to FIG. 2 for the method of saving and searching image adjusting parameter of the present invention, wherein the flowchart of searching the output parameter OUT comprising the steps of:

(100) inputting parameter value, that is inputting the above-mentioned input parameter IN and its range 0˜65535;

(110) finding output parameter corresponding to the (limit value)/2 from the maximum of the OUT, and as the maximum value of 255 and minimum value of 0 according to the present invention, and half of these two values is 128 and the corresponding address is 128($80), which is the critical value of the IN stored in the memory;

(120) comparing the existing critical value, which is the comparison between the above-mentioned input parameter IN and the existing critical value (maximum of the range);

(130) determining if it matches the range of the critical value, that is comparing the size of the IN range listed by such memory address, if yes, then go to Step (140); if no, then go to Step (140A);

(140) converting the memory address into the output parameter, and it means that the compared memory address in the existing critical value range matches the input parameter IN, and therefore the address value of the memory address will be converted into output parameter OUT directly;

(150) outputting all output parameters, and that is outputting all output parameters OUT to the hardware control circuit or image processing software such that the comparison of the image for contrast, brightness, gamma correction effect during capture or output can meet the requirements for the input command.

(140A) obtaining the critical value for the next memory address by binary search, that is after the critical value and the IN value in a memory address is compared and there is no match, then the previous memory address is incremented by 1/2 or decremented by 1/2 to find a new comparing critical value by the binary search. The increment and decrement by 1/2 is based on the result of comparing the input parameter IN. If the IN value is larger than the critical value, then it increments by 1/2, otherwise decrements by 1/2.

In FIG. 2, it shows the flowchart of the searching procedure, and the method is not restricted. Either computer programs or hardware circuits can be used to accomplish the binary search comparison to find the OUT value. The following will further describe the principle of binary search. As shown in FIG. 2, assumed the maximum IN value is 65535, its value must be larger than the critical value of 128 stored in the memory address. Therefore, the memory address 128 is incremented by 1/2 (that is 64) to become 192, and the stored critical value must be smaller than the input parameter IN, therefore the memory address should be incremented by 1/2 (that is 32), and 32 is added to make it 224. The critical value is then smaller than the input parameter IN, therefore 1/2 (that is 16) is added to make it 240. The stored critical value is smaller than the IN, therefore 1/2 (that is 8) is added to make it 248, but the critical value is still less than the IN. Therefore 1/2 (that is 4) is added to make the value 252, but the critical value is still less than the IN. Therefore 1/2 (that is 2) is added to make the value 254, but the critical value is still less than the IN. Therefore 1/2 (that is 1) is added to make the value 255. The final result totally matches the critical value 65535, and therefore the corresponding memory address is 255, which is its output parameter OUT.

According to the binary search of the present invention, the formula for calculating the increment function of the OUT corresponding to the IN is listed below:

The OUT$(A) represents its output address, using INₘₐₓ to represent its corresponding critical value (the maximum input parameter value in the internal stored section), and N is used to represent the number of bits for OUT, and A1˜A_{N+1} represents its computation operator. The limit value for OUT=2^{N} and A₁=2^{N+1} if the INₘₐₓ₁=input parameter of the corresponding OUT$(A₁) or search the OUT$(A₁) for the second time. It represents the input parameter IN=INₘₐₓ₁ or falls within the range of the IN_{max1,} and then the OUT$(A)=output parameter OUT. If IN>IN_{max1,} then OUT$(A₂)=OUT$(A₁)+(A₁/2), and on the contrary, if IN<IN_{max1,} then OUT$(A₂)=OUT$(A₁)−(A₁/2). Similarly, under the status of OUT$(A₂), if IN>IN_{max2,} then OUT$(A₃)=OUT$(A₂)+(A₁/2²), or on the contrary, if IN<IN_{max2,} then OUT$(A₃)=OUT$(A2)−(A₁/2²). A general formula can be derived from this principle:

If IN>IN_{max (n),} then OUT$(Aₙ₊₁)=OUT$(Aₙ)+(A₁/2ⁿ), and the decimal points are round off to integer;

If IN<IN_{max (n),} then OUT$(Aₙ₊₁)=OUT$(Aₙ)−(A₁/2ⁿ), and the decimal points are round off to integer; OUT$(Aₙ₊₁)=OUT if IN=IN_{max (n)} or OUT$(Aₙ₊₁) is double searched; and wherein: n=1, 2,3 . . . n, n+1 (positive integer). Similarly when the output parameter OUT with respect to the input parameter IN is decreasing function, it also can derive the above formula, but the positive and negative signs are switched. In other words, the above formula can be used to clarify the principle of the present invention and in the meantime to use the derived formula on the design by direct hardware circuit or computer software program, which is useful for the industry.

According to the foregoing OUT searching comparison principle and method, we can derive each of the other values by the comparison method similarly. For example, if IN falls in any value between 65000˜65535, when compared by the above binary search, the memory address 255 will be used repeatedly for two times (that is in the situation of +0 or −0) because the critical value has to be larger than the above IN. If it occurs, then the second comparison by binary search is no longer needed, and the memory address selected for repeating the process for second time is used for the final output value OUT. Therefore, we can derive in order the memory addresses corresponding to the final parameter output of the IN values and the output parameter similarly.

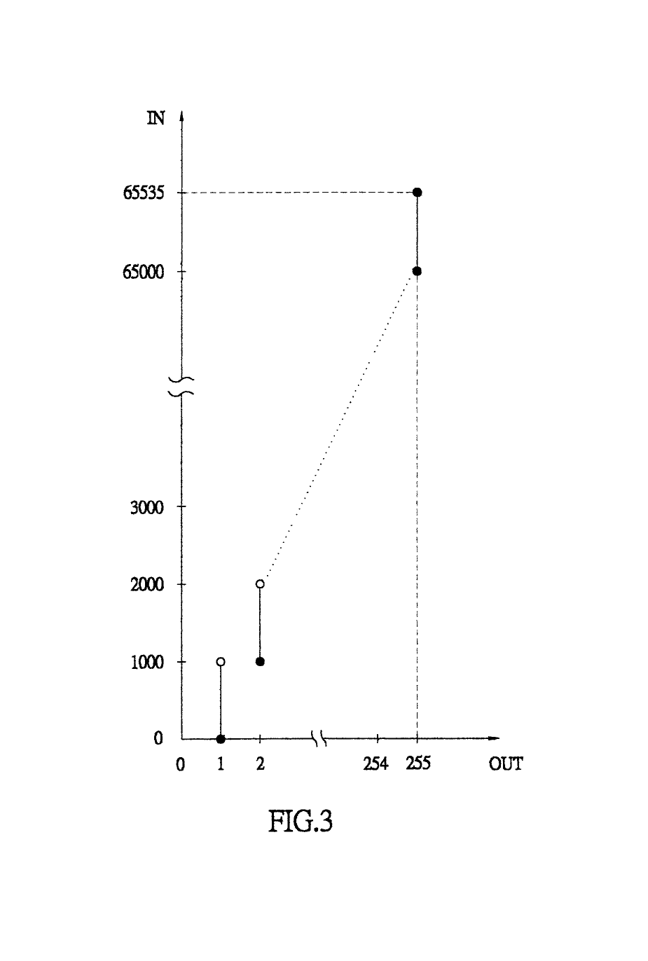

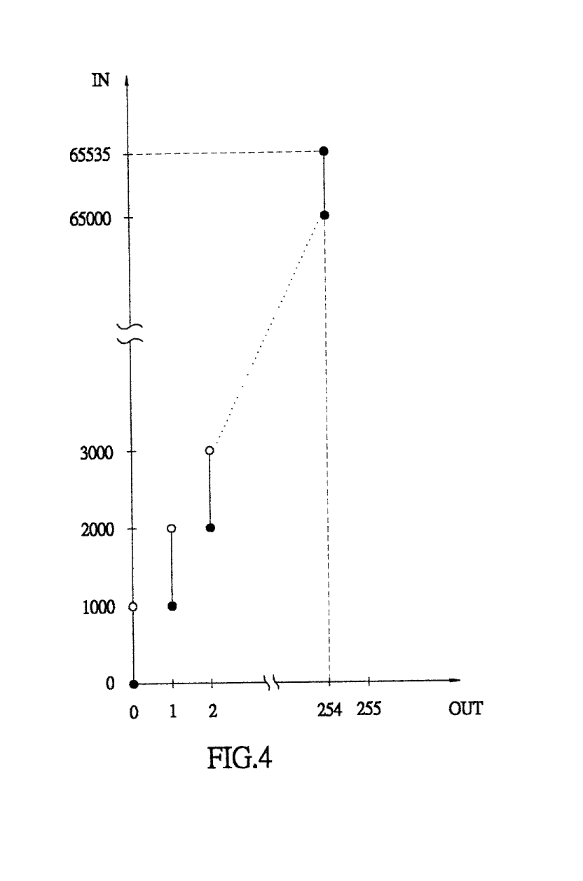

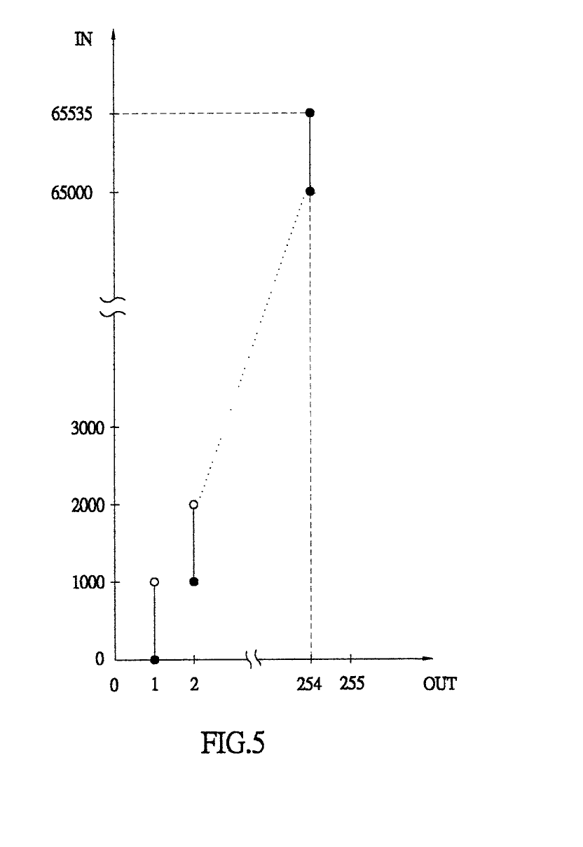

Please refer to FIGS. 3, 4, and 5 for the method of saving and searching image adjusting parameter according to the present invention, and there are several embodiments for performing the increment or decrement on the discrete function between the IN value and the OUT value. As in the second, third, and fourth embodiments, wherein the one shown in FIG. 3 differs from the first embodiment by 0≦IN≦65535 and 0<OUT≦255, and 0 is not included in the output parameter OUT and the number of output values is below 255. The third embodiment shown in FIG. 4 has 0≦IN≦65535 and 0≦OUT<255, and 255 is not included in the output parameter OUT and the number of output values is below 255. The fourth embodiment shown in FIG. 5 has 0≦IN≦65535 and 0<OUT<255, and both 0 and 255 are not included in the output parameter OUT and the number of output values is below 254. Regardless of the second, third, and fourth embodiments, the difference of the function mapping between the IN and OUT can be obtained from the final output OUT from the saving and searching method as shown in FIGS. 1 and 2.

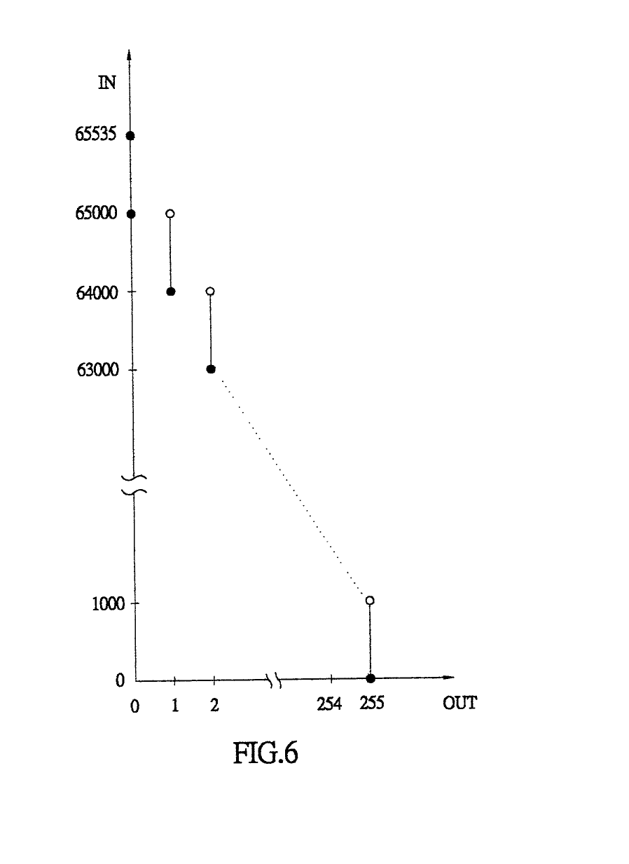

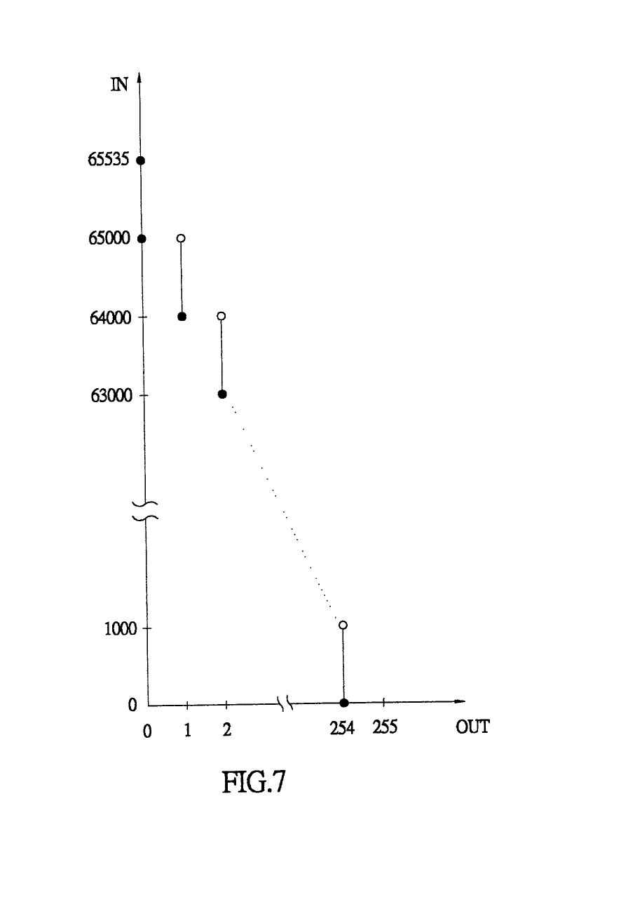

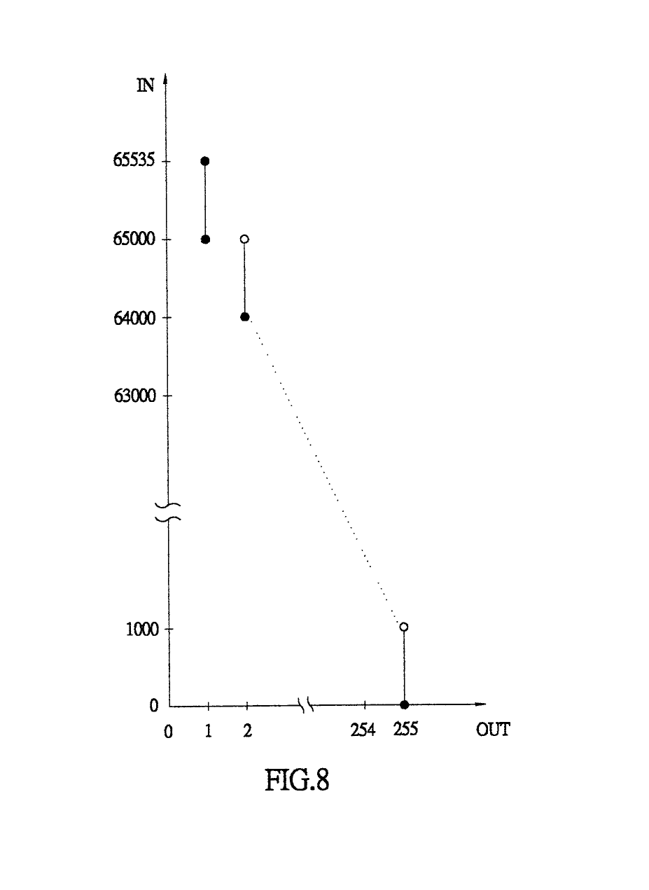

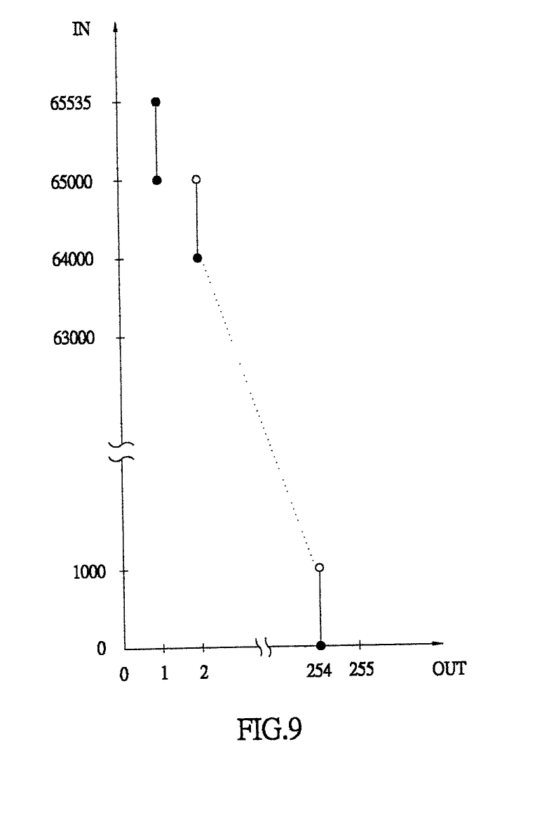

Please refer to FIGS. 6, 7, 8, and 9 which show the method of saving and searching image adjusting parameter according to the present invention, and there are other embodiments for performing the discrete decrement function mapping between IN and OUT. In FIGS. 5, 6, 7, and 8, wherein FIG. 6 shows an embodiment having the same as the first embodiment in 0≦IN≦65535 and 0≦OUT≦255, but opposite in the increment and decrement of the memory addresses. When IN is larger than the critical value in the memory address, the next memory address for the binary search comparison has to perform the decrement by 1/2, and on the contrary, if the IN is less than the critical value, then it has to be incremented by 1/2. The sixth embodiment shown in FIG. 7 has 0≦IN≦65535 and 0≦OUT<255, and 255 is not included in the OUT, and the number of OUT values is below 255. The seventh embodiment shown in FIG. 8 has 0≦IN≦65535 and 0<OUT≦255, and 0 is not included in the OUT, and the number of OUT values is below 255. The eighth embodiment shown in FIG. 9 has 0≦IN≦65535 and 0<OUT<255, and both 0 and 255 are not included in the OUT, and the number of OUT values is below 254.

Regardless of the fifth, sixth, seventh, and eighth embodiments, the difference of the function mapping between the IN and OUT can be obtained from the final output OUT from the saving and searching method as shown in FIGS. 1 and 2 and further obtains the corresponding output parameter OUT.

The method of saving and searching image adjusting parameter of the present invention is shown in FIGS. 1 to 9. We can clearly see that the memory space used in the present invention is smaller than the prior art one-to-one look-up table. To make it easier to understand, we take n bits input and 8 bits output for example, and the result is shown below:

| AFE or A/D | Traditional Address | The Present | Difference in Size |
|---|---|---|---|
| Converter Bits | Mapping (bits) | Invention (bits) | (Kbits) |
| 12 | 98304 | 9216 | 87.0 |
| 14 | 393216 | 10752 | 373.5 |
| 16 | 1572864 | 12288 | 1524.0 |
| 18 | 6291456 | 13824 | 6130.5 |
| 20 | 25165824 | 15360 | 24561.0 |

From the results shown in the above table, it further shows that when the number of bits of the IN (the number of converted bits shown in the fist column in the table) gets larger, the final number of different bits is larger, and increases in multiple progression. In other words, when the number of bits reaches 20, the present invention just needs 15 Kbits memory space, but the prior art one-to-one look-up table needs about 25000 Kbits memory space. No matter the hardware circuit design or cost, it is a burden. As the volume of scanners or other applied image capture devices will be larger for such application, which has problem in its applications. The present invention breaks through the bottleneck and reduces the memory size drastically, in the meantime it also reduces the size of the scanner or image capture device in great extent, which are useful to the industry.

The purpose of the present invention resides in the simplest and most convenient way for saving and searching the image output parameters in order to reduce the overall memory space, in the meantime it reduces the volume of the scanner or other image capture devices in great extent so that it cuts the costs for product manufacturing and circuit design, and further enhance the industrial value.

Therefore, in summation of the above description, the present invention obviously attains the objective of the present invention. The inventor of the present invention based on years of experience in the related industry conducted extensive research to enhance the structure of the present invention herein which is hereby submitted for patent application.

While the invention has been described in what is considered the most practical and preferred embodiments, it is understood that the invention is not limited to the disclosed embodiments, but is intended to cover various modifications and similar arrangements and procedures within the spirit and scope of the broadest interpretation and equivalent arrangements, modifications, and procedures.

What is claimed is:

1. A method for saving and searching image adjusting parameter, used for an output parameter of digital image adjustment for an image capture equipment, wherein the output parameter is divided into a plurality of memory address in order, and a critical value which is selected one from maximum and minimum input parameter values in the range is saved into each of said memory addresses, and after the input image adjusting parameter is inputted, the critical value and the input parameter value is obtained by binary search comparison from half of the maximum parameter value of the corresponding memory address, and the increment or the decrement binary search comparison is repeated according to the comparison result to obtain the next comparing memory address and the critical value for the comparison until the range of critical value of the input parameter of the memory address is searched, and the numeric value of the memory address is converted directly to the output parameter value to obtain the image adjusting output parameter corresponsive to the input parameter value.

2. A method for saving and searching image adjusting parameter as claimed in claim 1, wherein said output parameter value is the adjusting parameter for the contrast, brightness, and gamma correction of the digital image.

3. A method for saving and searching image adjusting parameter as claimed in claim 1, wherein said input parameter value shows a many-to-one function mapping relation.

4. A method for saving and searching image adjusting parameter as claimed in claim 3, wherein said function mapping relation is an increasing and discontinuous function.

5. A method for saving and searching image adjusting parameter as claimed in claim 3, wherein said function mapping relation is a decreasing and discontinuous function.

6. A method for saving and searching image adjusting parameter as claimed in claim 1, wherein each of said output parameter is equal to its corresponding memory address value.
